(19) United States
(12) Patent Application Publication
(10) Pub. No.: US 2018/0025931 A1
(43) Pub. Date: Jan. 25, 2018

(54) PROCESSED WAFER AS TOP PLATE OF A WORKPIECE CARRIER IN SEMICONDUCTOR AND MECHANICAL PROCESSING

(71) Applicant: APPLIED MATERIALS, INC., Santa Clara, CA (US)

(72) Inventors: Srinivas D. Nemani, Sunnyvale, CA (US); Shambhu N. Roy, Fremont, CA (US); Gautam Pisharody, Newark, CA (US); Douglas A. Buchberger, JR., Livermore, CA (US); Ellie Y. Yieh, San Jose, CA (US); Zhong Qiang Hua, Saratoga, CA (US)

(21) Appl. No.: 15/217,328

(22) Filed: Jul. 22, 2016

(51) Int. Cl. H01L 21/683; C23C 16/513

(52) U.S. Cl. CPC H01L 21/6833; C23C 16/513

(57) ABSTRACT

A processed wafer is described that may be used as a workpiece carrier in semiconductor and mechanical processing. In some examples, the workpiece carrier includes a substrate, an electrode formed on the substrate to carry an electric charge to grip a workpiece, a through hole through the substrate and connected to the electrode, and a dielectric layer over the substrate to isolate the electrode from the workpiece.

### FIELD

The present description relates to workpiece carriers for semiconductor and mechanical processing and, in particular, to a processed wafer as a workpiece carrier.

### BACKGROUND

In the manufacture of micromechanical and semiconductor chips, a workpiece, such as a silicon wafer or other substrate is exposed to a variety of different processes in different processing chambers. The chambers may expose the wafer to a number of different chemical and physical processes whereby minute integrated circuits and micromechanical structures are created on the substrate. Layers of materials which make up the integrated circuit are created by processes including chemical vapor deposition, physical vapor deposition, epitaxial growth, and the like. Some of the layers of material are patterned using photoresist masks and wet or dry etching techniques. The substrates may be silicon, gallium arsenide, indium phosphide, glass, or other appropriate materials.

The processing chambers used in these processes typically include a substrate support, pedestal, or chuck to support the substrate during processing. In some processes, the pedestal may include an embedded heater to control the temperature of the substrate and, in some cases, to provide elevated temperatures that may be used in the process. An electrostatic chuck (ESC) has one or more embedded conductive electrodes to generate an electric field that holds the wafer on the chuck using static electricity.

An ESC will have a top plate, referred to as a puck, a bottom plate or base, referred to as a pedestal, and an interface or bond to hold the two together. The top surface of the puck has a contact surface that holds the workpiece which can be made of various materials, e.g. silicon, polymers, ceramic, or a combination, and may have coatings all over or over selective locations, etc. A variety of components are embedded into the puck including electrical components for holding or chucking the wafer, and thermal components for heating the wafer.

There is a constant drive to make integrated circuit chips smaller. Part of this includes thinning the back side of a wafer before and after circuit components are built on the front side of the wafer. The thinned wafer is much smaller but is brittle so it is bonded to the puck with an adhesive tape. This helps to prevent the thinned wafer from being damaged if it falls off the puck. While this holds the wafer securely, it is more difficult to attach and remove the wafer than with an electrostatic chuck. In addition, the adhesive serves as an electrical and thermal insulator between the wafer and the puck of the ESC.

### BRIEF SUMMARY

A processed wafer is described that may be used as a workpiece carrier in semiconductor and mechanical processing. In some examples, the workpiece carrier includes a substrate, an electrode formed on the substrate to carry an electric charge to grip a workpiece, a through hole through the substrate and connected to the electrode, and a dielectric layer over the substrate to isolate the electrode from the workpiece.

### BRIEF DESCRIPTION OF THE DRAWINGS

Embodiments of the present invention are illustrated by way of example, and not limitation, in the figures of the accompanying drawings in which:

FIG. 1 is a cross-sectional side view diagram of a carrier wafer and thinned workpiece wafer attached together according to an embodiment;

FIG. 2 is a top plan view of a carrier wafer showing an application of electrodes before the application of a dielectric layer according to an embodiment;

FIG. 3 is an isometric view of a carrier wafer with a mask applied before electrodes are deposited according to an embodiment;

FIG. 4 is a side cross-sectional view of the carrier wafer of FIG. 3 according to an embodiment;

FIG. 5 is top plan view of a carrier wafer showing the application of an alternative electrode configuration before the application of a dielectric layer according to an embodiment;

FIG. 6 is an isometric view of a carrier wafer with a stencil for the application of a further alternative electrode configuration before the application of a dielectric layer according to an embodiment;

FIG. 7 is a cross-sectional side view diagram of a portion of a carrier showing two types of holes according to an embodiment;

FIG. 8 is a process flow diagram of producing a carrier according to an embodiment;

FIG. 9 is a side cross-sectional view of an alternative carrier according to an embodiment;

FIG. 10 is a side cross-sectional view of a variation of the carrier of FIG. 9 according to an embodiment;

FIG. 11 is an isometric view of an assembled electrostatic chuck carrying a carrier according to an embodiment;

FIG. 12 is a partial cross sectional view of a plasma system having a pedestal or ESC capable of carrying a workpiece and a carrier according to an embodiment.

### DETAILED DESCRIPTION

As described herein, a regular silicon wafer may be used as a substrate of a wafer carrier and an ESC may be built on the carrier wafer with very little additional thickness by using semiconductor fabrication processes. A thinned workpiece wafer may be electrostatically chucked to the silicon carrier wafer. Attachment and separation are quick and simple using electrodes near the top of the silicon carrier wafer. The thinned workpiece wafer is protected from physical stresses by the carrier wafer and the carrier wafer and workpiece wafer together are about the same size as a conventional thick wafer. As a result, the chucked assembly of workpiece and carrier works well with existing tools and fabrication processes.

Such a carrier has been referred to as a transfer ESC. The thinned wafer may be electrostatically attached to the carrier by connecting electrical leads to contacts on the carrier and applying a charge to the carrier electrodes. The carrier wafer then maintains the charge and its grip on the thinned wafer as the assembly is moved to different processes and locations. When appropriate, the electrostatic charge is released by connecting electrical leads with a reversed polarity.

Electrodes to electrostatically hold the workpiece wafer may be deposited on the carrier wafer using a PVD (Plasma Vapor Deposition) tool, for example. This allows for very thin and high quality electrodes. Dielectric layers may be deposited on the wafer using, for example, a CVD (Chemical Vapor Deposition) tool. This allows for high quality dielectric layers as needed for high electrostatic forces. The precision of older plasma processing equipment is more than sufficient to form electrodes to hold the workpiece.

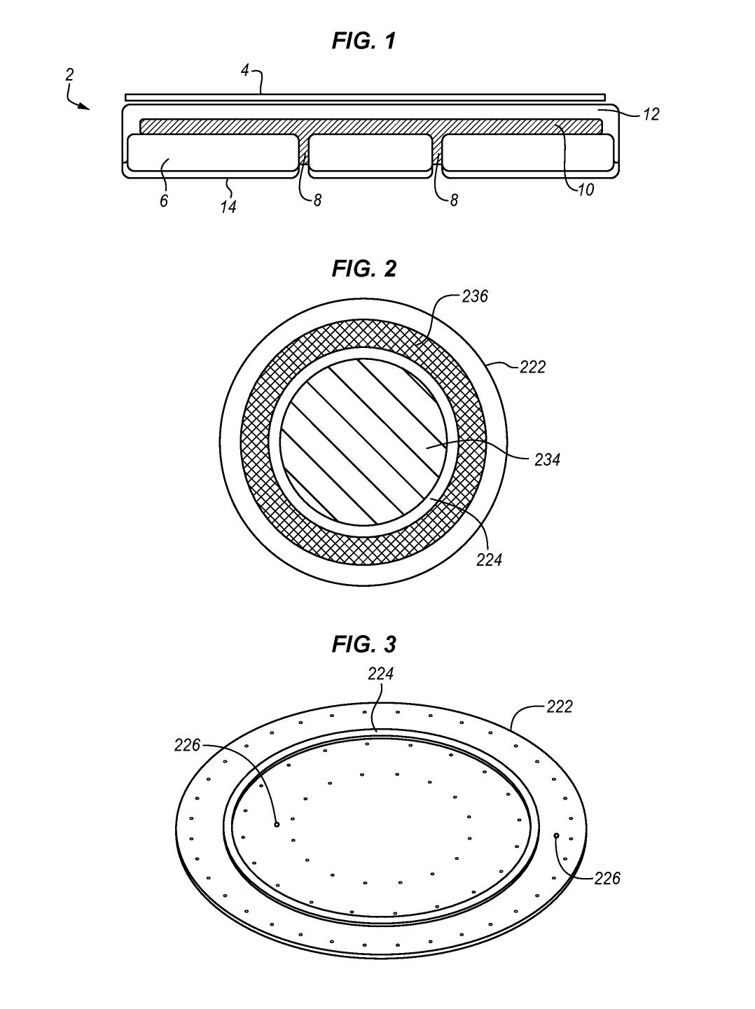

FIG. 1 is a cross-sectional side view diagram of a carrier wafer 2 and thinned workpiece wafer 4 attached together. The carrier wafer is based on a silicon substrate 6. This may be a substrate of the same type as the workpiece wafer. Using the same materials avoids any stresses caused by thermal expansion and contraction. Just as the workpiece wafer may be made of different materials, the carrier wafer may also be made of any of the same materials. Alternatively a different material with a similar coefficient of thermal expansion to the workpiece wafer may be used.

A set of holes 8 are drilled, etched, or bored through the substrate. The illustrated holes are contact holes. There may be additional holes for lift pins, a back side gas, a vacuum fitting or other purposes. In some embodiments, the holes may be used to release the workpiece after the electrostatic charge is released. A pin or air pressure may be applied to the holes to push the backside of the thinned wafer off the carrier wafer. The holes may be plated or filled with tantalum, copper, aluminum, or another conductive material so that the walls or the fillings of the holes may serve as contacts or contact points or pads for electrical leads.

Electrodes 10 are applied over the substrate as a layer. This layer or another layer may extend into the holes 8 so that the holes are plated inside. In this way the plated holes may be used as electrical connections to the electrodes on the opposite side. This allows electrical access to the electrodes when the electrodes are covered by a workpiece wafer. The electrodes may be formed of tantalum, copper, aluminum, or made of any of a variety of other conductive materials.

The electrodes may be made in a pattern using conventional silicon patterning and masking techniques. Any of a variety of different patterns may be used, including dipole, concentric, and star patterns, etc. Additional patterns are described and shown below.

Because the carrier wafer is formed of silicon, any of a variety of silicon processing techniques may be applied. In some embodiments a layer of tantalum about 1 μm thick is applied to the top of the carrier wafer and the inner walls of the holes using PVD (Plasma Vapor Deposition). Alternatively any of a variety of other processes may be used to apply copper, aluminum, tantalum, or other conductive materials or combination of materials to the silicon.

The electrodes are then encapsulated and covered by a dielectric layer 12. The dielectric layer may be applied by CVD (Chemical Vapor Deposition) or in any other way, as desired. The dielectric layer allows the static charge to be maintained between the conductive electrodes and the workpiece wafer because the dielectric layer is between the electrodes and the workpiece carrier when the workpiece carrier is in use.

In some embodiments, the workpiece carrier is flipped after applying the dielectric and a layer of dielectric 14 is also applied to the back side of the workpiece wafer. Holes may be etched into the dielectric to expose the holes 108 in the carrier and allows access to the electrical contacts, gas fittings, and any other components. In this example, the back side dielectric is in contact with the substrate with no intervening metal layer. The metal layer 10 on the front side serves as the electrode and the through holes 8 allow electrical contact with the electrode so that there is no need for a metal layer on the back side.

FIG. 2 is a top plan view of the carrier wafer showing an application of electrodes before the application of the dielectric layer. A silicon carrier wafer 222 has a concentric bipolar electrode configuration with an inner central electrode 234 and an outer peripheral electrode 236. Different charge polarities may be applied to the two electrodes to provide a more secure electrostatic grip. Different through holes may be provided on the back side of the substrate as electrical contacts for the two different electrodes. To attach a workpiece, a current is applied with two different polarities, one polarity is applied to a contact for the inner electrode and the other polarity is applied as a contact for the outer electrode. To release the workpiece the connections are reversed to reverse the polarity until the charge is removed. Alternatively, the two contacts are connected together to allow the opposite charges to equalize, releasing the workpiece.

FIG. 3 is an isometric view of a silicon carrier wafer 222 with a mask 224 applied before the electrodes 234, 236 are deposited. The mask is formed of a PEEK (Polyetheretherketone) or any other suitable semi-rigid material that withstands the deposition process for the electrode. The mask may be applied to the substrate using an adhesive that releases with heat or a solvent.

This mask is suitable for a concentric design. When the electrodes are deposited as a thin layer over the substrate, the mask will cause a circular break in the layer causing there to be two concentric and disconnected circular metal patterns as shown in FIG. 2. The mask may then be removed leaving the two conductive electrodes with a break in between. In addition to the mask, contact holes 226 have been drilled or etched through the carrier wafer. There is at least one contact hole for each electrode, an inner and an outer. These will be in contact with the metal when the metal is deposited over or through the hole.

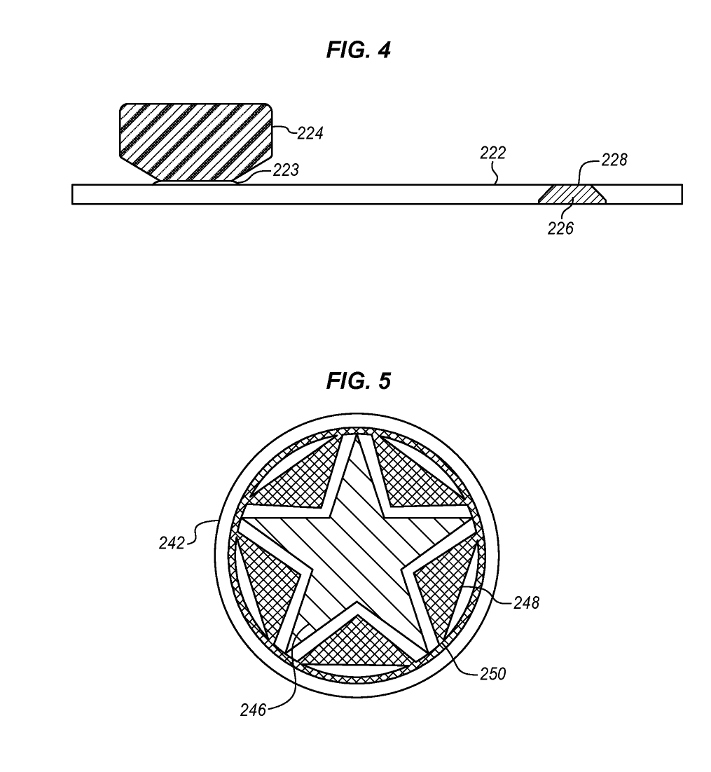

FIG. 4 is a cross-sectional side view diagram of the wafer 222 with a stencil or mask 224. In addition, there is a hole 226 with a plug 228. The plug may be conductive so that it makes electrical contact with the applied electrode layer and provides a contact for the back surface as described above. An additional contact (not shown) may be applied to the back side of the wafer in electrical contact with the plug 228. Such an additional contact may make it easier to make a contact with the plug.

The stencil may be attached with an adhesive 223. The adhesive may be an adhesive backing such as a PSA (pressure sensitive adhesive of acrylic, silicone, etc.). The adhesive may alternatively be a spray, brush-on, or similarly dispensed adhesive that is selectively applied so that the rest of the front side of the substrate is not affected. The stencil is removed after the electrodes are deposited and before the electrodes are encapsulated by dielectric. In some embodiments, the stencil is formed of a suitable dielectric material and is left in place after the electrodes are deposited. In such a case, the stencil is encapsulated and serves as part of the dielectric.

FIG. 5 is a top plan view of a carrier wafer with another electrode configuration before the dielectric layer is applied. In this example, the carrier 242 has an inner electrode 246 and an outer electrode 248 with an insulating space 250 in between. These electrodes are interdigitated with bipolar electrodes. In other words, a digit of the central electrode extends out toward the periphery between two digits of the outer electrode. Such a shape may easily be formed using a different stencil or mask design and applying the same process as suggested by FIGS. 3 and 4.

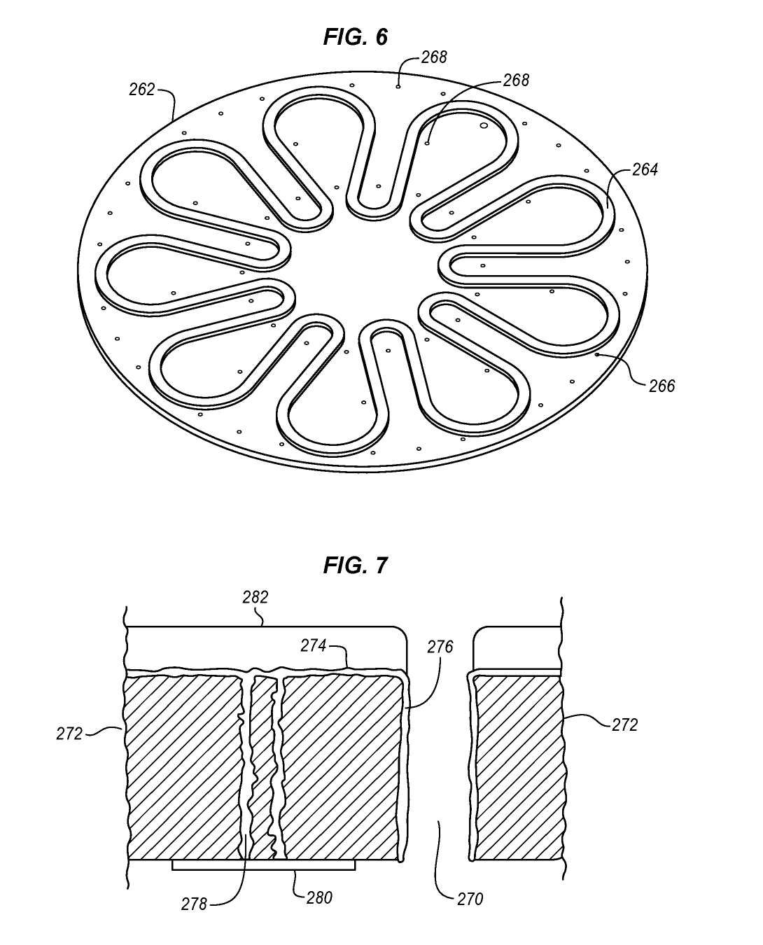

FIG. 6 is an isometric view of a silicon carrier wafer 262 with a different mask 264 applied to the surface. This mask will provide a different interdigitated design for a bipolar electrode configuration. The examples of FIGS. 2, 5, and 6 are provided to show different possibilities. Many other shapes and configurations may be used to provide the desired gripping characteristics, depending on the particular implementation.

The wafer also has a plurality of vacuum holes 266. The holes are sized to be larger in diameter than the thickness of the electrode plating. As a result, they are not filled when the electrode is applied by plating or deposition. The holes may be used to apply a vacuum to hold the workpiece, and to provide positive air pressure to push the workpiece off the carrier for de-chucking, or for any other desired purpose. Holes may also be provided for lift pins, etc. Another set of holes 268 are smaller in diameter and will be filled by the electrode layer deposition. Alternatively, a plug 228 may be applied over these holes as in FIG. 4 so that electrical contact may be made with the electrode from the back side of the wafer. After the electrode is applied over each plug, the plug will be in contact with the electrode and will be accessible from the back side of the hole.

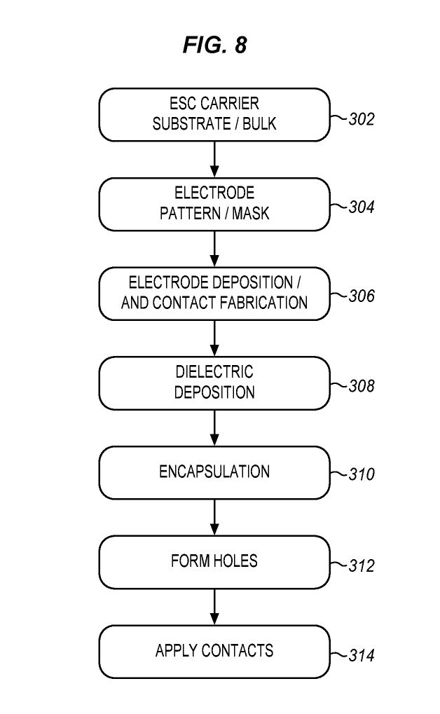

FIG. 7 is a cross-sectional side view diagram of a portion of a workpiece carrier showing an example of two types of the holes that may be used with the present workpiece carrier. A substrate 272, such as a silicon wafer as described above, has a large through hole 270 that extends through the substrate. The electrode layer 274 is applied over the substrate after the through hole has been made. The deposited metal 274 on the top of the substrate serves as an electrode. The deposited metal 276 extends into the large through hole and lines or plates the sides of the through hole. In some cases, this lining may be used to provide an electrical connection to the electrode. As shown, the lining is integral with the electrode and electrically connected to the electrode. The through hole plating 276 may be formed while the electrode is deposited. This larger hole may also be used for vacuum ports, lift pins and other purposes.

Another type of hole 278 is smaller and is completely filled with the metal layer. The conductive material or metal in this case is not a lining as with the larger hole, but a filling. Similar to the larger hole, the metal filled via also provides an electrical connection to the electrode on the front side of the substrate from the back side of the substrate. This smaller hole is small enough that the opening is covered over with the top electrode metal layer 274. Additional operations may be performed to ensure that the hole is filled with the conductive material. As such the metal hole provides electrical access to the electrode. In this example, there are two smaller holes near each other as indicated by the substrate material 272 between the metal layers.

The back side electrical access may be improved by flipping over the substrate and forming a bond pad 280 over one or more of the holes. In this example, the bond pad covers the two illustrated filled holes. The bond pad may be formed by another metal layer deposition step, by printing, or in any of a variety of other ways. The bond pad provides a secure and convenient connection for electrical leads. As described above, the leads may be used to apply a current to the electrodes to electrostatically charge the electrodes and hold the workpiece to the carrier.

A dielectric layer 282 is applied over the electrode 274 to maintain the electrostatic charge. The dielectric layer may be so thin that it does not fill the large hole 270, or the hole may be masked or plugged while the dielectric layer is applied. Alternatively, the hole may be filled and then reopened after the dielectric is applied.

FIG. 8 is a process flow diagram of producing a substrate carrier as described above. The operations begin at 302 with a bulk carrier substrate. This substrate may be a standard silicon wafer of any desired shape or size such as a round 300 mm wafer. Alternatively it may be made of other materials such as glass, polysilicon, gallium arsenide, etc. AlN or Al₂O₃ or any other ceramic materials may also be used. These materials are strong and easy to machine. For use in carrying a silicon wafer, a silicon substrate works well because its behavior and properties mimic that of a standard wafer. This allows the carrier to be used with existing wafer processing tools.

The substrate may be prepared by thinning, or by drilling or etching the through holes described above. In some cases, some of the holes are filled with plugs 228. Other processes may be performed to prepare the surface such as polishing, applying coatings, etc.

At 304, the substrate is masked for applying the electrode. The mask may be a pre-formed stencil produced from a metal or plastic material. Such a stencil may be made apart from the stencil and then attached using an adhesive. Alternatively, the stencil may be formed directly on the substrate using photolithography, inkjet, or other processes. This pattern is over the front side of the wafer on the surface that is to be facing the workpiece.

As a further alternative, polyetheretherketone (PEEK) or polymethylmethacrylate (PMMA) may be applied in a pattern as a stencil. For particularly fine electrode patterns, photolithography may be used.

There are a variety of different stencil shapes and patterns that may be used. A concentric circular design is useful for surviving rotations when chemical mechanical polishing (CMP) is applied to the workpiece. Concentric interdigitated designs provide improved chucking for non-conductive targets.

At 306, the electrode is deposited over the stencil and into or through the holes to form the contacts. PVD may be used to apply Ti or Ta over the front side or top surface of the substrate. Ti plugs may first be inserted into the holes to provide electrical connections from the back side depending on the particular implementation. Alternatively, the holes may be lined during the PVD application of the electrode. In some embodiments, the sides or edges of the substrate are exposed so that the PVD Ti or Ta layer wraps around the sides of the substrate. This allows electrical connection to be made from the back side of the substrate more easily. A wrap around electrode design eliminates a need for mechanical contacts on the back side of the wafer using through holes or filled holes. Using PVD for electrode deposition allows for many different electrode designs to be produced. As mentioned above, there may be separate electrodes on the surface to allow for different polarities to be stored across the top surface of the carrier. PVD films allow for a wider choice of different electrode materials to suit different applications.

At 308 a dielectric layer is deposited over the electrodes. The dielectric layer protects the electrode and provides the insulating layer to maintain the electrostatic charge when a workpiece is being electrostatically held to the carrier. The dielectric may be deposited in any of a variety of different ways. A thin PVD application of SiN provides good isolation for the anticipated electrostatic charges. Alternatively a plasma spray of alumina or yttria may be used.

At 310, the substrate is encapsulated. The encapsulation is shown as being on the front side and the back side of the substrate. A polymer tape or polymer coating may be used for this purpose. Other types of dielectrics may alternatively be used.

At 312 holes may be formed through the substrate from the back side to the front side. As mentioned above, holes may be formed before the patterns are applied at 304 or at any other time in the process. The holes may be formed by drilling etching, machining, or in any of a variety of other ways. Additional purging or vacuum holes or both may be added to provide a dual chucking capability. Accordingly the workpiece such as a wafer may be held using an electrostatic charge as with an ESC. In addition, for some operations, the vacuum holes through the substrate may be used for vacuum chucking to provide a still stronger grip on the workpiece. The holes may also or alternatively be used for purging the thin wafer or for vacuum de-chucking

At 314 contacts may optionally be applied to the back side of the substrate. One or more of the through holes may be made with a conductive deposition on the walls of the hole or solid vias as shown above. Other through holes may have solid contact plugs inserted into the holes. This provides a closure and contact over the holes when the deposition is only on the inner walls of the holes and does not fill the hole. In either or both cases, metal bond pads may be deposited from the back side of the substrate to make charging contacts.

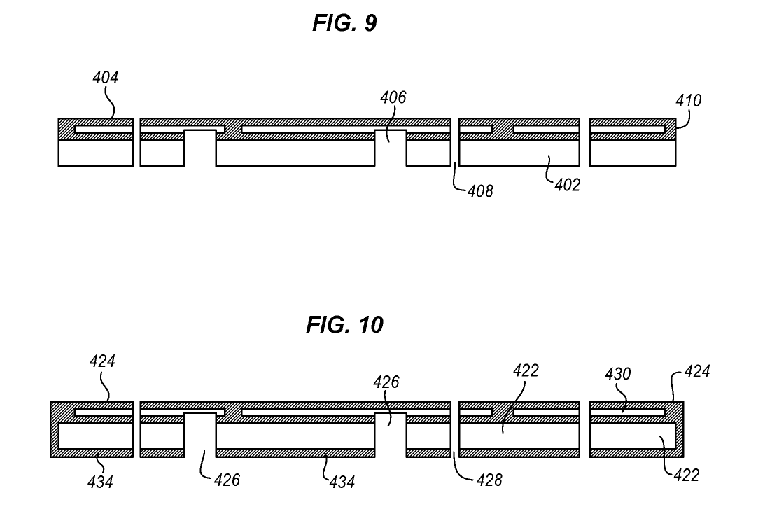

FIG. 9 is a side cross-sectional view of an example of an alternative implementation of a substrate-based workpiece carrier. In this example, a substrate 402, such as a silicon or glass substrate provides the structure of the carrier. This may be a 300 mm silicon wafer or another type of substrate as in the examples above. In this example, instead of forming electrodes directly on the substrate and then forming a dielectric over the substrate, the electrodes are formed within the dielectric. A dielectric sheet 404, such as a 300 mm polyimide sheet surrounds and encapsulates electrodes 410 which are conductive and may be in any of the patterns shown above or any other desired pattern.

The dielectric sheet is attached to the substrate with any suitable adhesive. The substrate and polyimide are then bored from the back side. Holes 406 through the back side reach to the electrode 410 within the dielectric 404 to allow an electrical connection to the electrodes. These holes allow the electrodes to be charged and discharged. Additional holes 408 may be drilled or etched all the way through both the substrate and the dielectric sheet for vacuum, de-chucking and other purposes.

FIG. 10 is a side cross-sectional view of a variation of the substrate-based workpiece carrier of FIG. 9. In this example, the substrate 422 carries a polyimide sheet 424 with an embedded electrode 430 to electrostatically chuck a workpiece (not shown). In this example, the substrate also has a backside layer of polyimide 434 that extends around the sides of the substrate to the top sheet. This allows the substrate to be fully encapsulated so that the entire carrier is fully insulated. The same types of holes 426, 428 as in FIG. 9 may be provided to charge the electrodes and allow other access to the workpiece through the back side of the carrier.

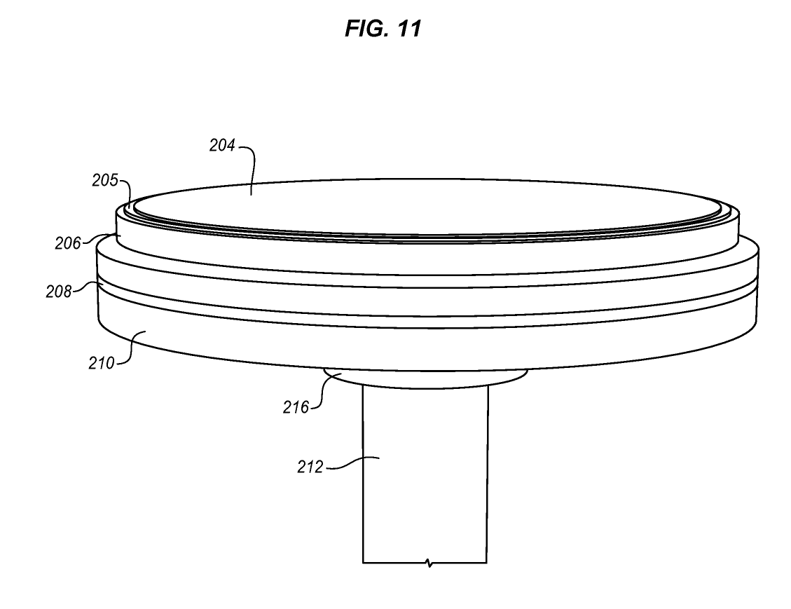

FIG. 11 is an isometric view of an assembled electrostatic chuck carrying the workpiece carrier described above. A support shaft 212 supports a base plate 210 through an isolator 216. A middle isolator plate 208 and an upper cooling plate 206 are carried by the base plate. The top cooling plate 206 carries a dielectric puck 205 on the top surface of the cooling plate. The puck has an upper circular platform to support a workpiece 204. The puck 205 may have internal electrodes to electrostatically attach the workpiece. The workpiece may alternately be clamped, vacuumed or attached in another way. There is an adhesive bond between the puck 205 and the top cooling plate 206 to hold the ceramic of the top plate to the metal of the cooling plate. Heaters may be formed in the top plate or the middle plate 208.

The ESC is able to control the temperature of the workpiece using resistive heaters in the puck, coolant fluid in the cooling plate, or both. Electrical power, coolant, gases, etc. are supplied to the coolant plate 206 and the puck 205 through the support shaft 212. The ESC may also be manipulated and held in place using the support shaft.

The workpiece 204 of this diagram includes both the workpiece 4 of FIG. 1 and the workpiece carrier 2. The two are clamped together using electrostatic forces and may then be treated as a single part. The combined carrier and workpiece are held to the chuck using any of a variety of different methods. The ESC of FIG. 11 is provided as an example, the combined workpiece 4 and carrier 2 may be carried in any of a variety of different pedestals, carriers, transfer chucks, or other holders, depending on the processing that is to be applied to the workpiece.

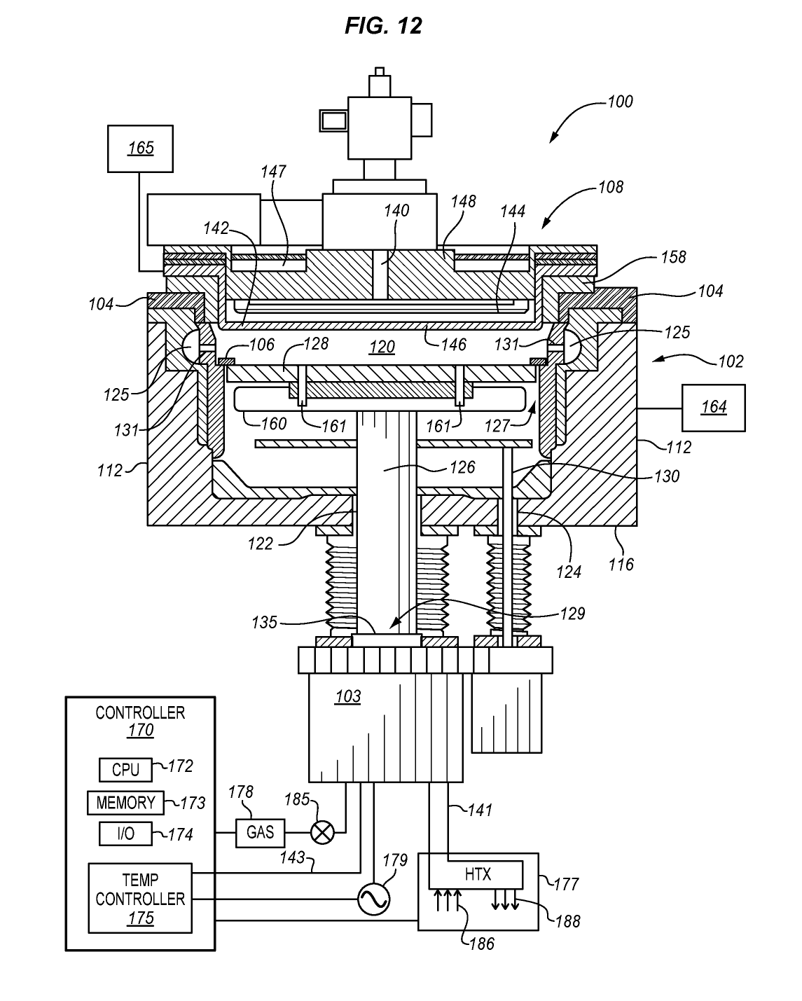

FIG. 12 is a partial cross sectional view of a plasma system 100 having a pedestal 128 or ESC capable of carrying a workpiece and carrier according to embodiments described herein. The pedestal 128 has an active cooling system which allows for active control of the temperature of a workpiece positioned on the pedestal over a wide temperature range while the workpiece is subjected to numerous process and chamber conditions. The plasma system 100 includes a processing chamber body 102 having sidewalls 112 and a bottom wall 116 defining a processing region 120.

A pedestal, carrier, chuck or ESC 128 is disposed in the processing region 120 through a passage 122 formed in the bottom wall 116 in the system 100. The pedestal 128 is adapted to support a workpiece (not shown) on its upper surface. The workpiece may be any of a variety of different workpieces for the processing applied by the chamber 100 made of any of a variety of different materials. The pedestal 128 may optionally include heating elements (not shown), for example resistive elements, to heat and control the workpiece temperature at a desired process temperature. Alternatively, the pedestal 128 may be heated by a remote heating element, such as a lamp assembly.

The pedestal 128 is coupled by a shaft 126 to a power outlet or power box 103, which may include a drive system that controls the elevation and movement of the pedestal 128 within the processing region 120. The shaft 126 also contains electrical power interfaces to provide electrical power to the pedestal 128. The power box 103 also includes interfaces for electrical power and temperature indicators, such as a thermocouple interface. The shaft 126 also includes a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is used to activate substrate lift pins 161 disposed through the pedestal 128. The substrate lift pins 161 lift the workpiece off the pedestal top surface to allow the workpiece to be removed and taken in and out of the chamber, typically using a robot (not shown) through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146.

A radio frequency (RF) source 165 is coupled to the showerhead assembly 142. The RF source 165 powers the showerhead assembly 142 to facilitate generation of plasma between the faceplate 146 of the showerhead assembly 142 and the heated pedestal 128. In one embodiment, the RF source 165 may be a high frequency radio frequency (HFRF) power source, such as a 13.56 MHz RF generator. In another embodiment, RF source 165 may include a HFRF power source and a low frequency radio frequency (LFRF) power source, such as a 300 kHz RF generator. Alternatively, the RF source may be coupled to other portions of the processing chamber body 102, such as the pedestal 128, to facilitate plasma generation. A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120 in very close proximity to the sidewalls 101, 112 of the chamber body 102 to prevent exposure of the sidewalls 101, 112 to the processing environment within the processing region 120. The liner assembly 127 includes a circumferential pumping cavity 125 that is coupled to a pumping system 164 configured to exhaust gases and byproducts from the processing region 120 and control the pressure within the processing region 120. A plurality of exhaust ports 131 may be formed on the chamber liner assembly 127. The exhaust ports 131 are configured to allow the flow of gases from the processing region 120 to the circumferential pumping cavity 125 in a manner that promotes processing within the system 100.

A system controller 170 is coupled to a variety of different systems to control a fabrication process in the chamber. The controller 170 may include a temperature controller 175 to execute temperature control algorithms (e.g., temperature feedback control) and may be either software or hardware or a combination of both software and hardware. The system controller 170 also includes a central processing unit 172, memory 173 and input/output interface 174. The temperature controller receives a temperature reading 143 from a sensor (not shown) on the pedestal. The temperature sensor may be proximate a coolant channel, proximate the wafer, or placed in the dielectric material of the pedestal. The temperature controller 175 uses the sensed temperature or temperatures to output control signals affecting the rate of heat transfer between the pedestal assembly 142 and a heat source and/or heat sink external to the plasma chamber 105, such as a heat exchanger 177.

The system may also include a controlled heat transfer fluid loop 141 with flow controlled based on the temperature feedback loop. In the example embodiment, the temperature controller 175 is coupled to a heat exchanger (HTX)/chiller 177. Heat transfer fluid flows through a valve (not shown) at a rate controlled by the valve through the heat transfer fluid loop 141. The valve may be incorporate into the heat exchanger or into a pump inside or outside of the heat exchanger to control the flow rate of the thermal fluid. The heat transfer fluid flows through conduits in the pedestal assembly 142 and then returns to the HTX 177. The temperature of the heat transfer fluid is increased or decreased by the HTX and then the fluid is returned through the loop back to the pedestal assembly.

The HTX includes a heater 186 to heat the heat transfer fluid and thereby heat the substrate. The heater may be formed using resistive coils around a pipe within the heat exchanger or with a heat exchanger in which a heated fluid conducts heat through an exchanger to a conduit containing the thermal fluid. The HTX also includes a cooler 188 which draws heat from the thermal fluid. This may be done using a radiator to dump heat into the ambient air or into a coolant fluid or in any of a variety of other ways. The heater and the cooler may be combined so that a temperature controlled fluid is first heated or cooled and then the heat of the control fluid is exchanged with that of the thermal fluid in the heat transfer fluid loop.

The valve (or other flow control devices) between the HTX 177 and fluid conduits in the pedestal assembly 142 may be controlled by the temperature controller 175 to control a rate of flow of the heat transfer fluid to the fluid loop. The temperature controller 175, the temperature sensor, and the valve may be combined in order to simplify construction and operation. In embodiments, the heat exchanger senses the temperature of the heat transfer fluid after it returns from the fluid conduit and either heats or cools the heat transfer fluid based on the temperature of the fluid and the desired temperature for the operational state of the chamber 102.

Electric heaters (not shown) may also be used in the ESC to apply heat to the workpiece assembly. The electric heaters, typically in the form of resistive elements are coupled to a power supply 179 that is controlled by the temperature control system 175 to energize the heater elements to obtain a desired temperature.

The heat transfer fluid may be a liquid, such as, but not limited to deionized water/ethylene glycol, a fluorinated coolant such as Fluorinert® from 3M or Galden® from Solvay Solexis, Inc. or any other suitable dielectric fluid such as those containing perfluorinated inert polyethers. While the present description describes the pedestal in the context of a PECVD processing chamber, the pedestal described herein may be used in a variety of different chambers and for a variety of different processes.

A backside gas source 178 such as a pressurized gas supply or a pump and gas reservoir are coupled to the chuck assembly 142 through a mass flow meter 185 or other type of valve. The backside gas may be helium, argon, or any gas that provides heat convection between the wafer and the puck without affecting the processes of the chamber. The gas source pumps gas through a gas outlet of the pedestal assembly described in more detail below to the back side of the wafer under the control of the system controller 170 to which the system is connected.

The processing system 100 may also include other systems, not specifically shown in FIG. 4, such as plasma sources, vacuum pump systems, access doors, micromachining, laser systems, and automated handling systems, inter alia. The illustrated chamber is provided as an example and any of a variety of other chambers may be used with the present invention, depending on the nature of the workpiece and desired processes. The described pedestal and thermal fluid control system may be adapted for use with different physical chambers and processes.

In operation, a workpiece is moved through the opening of the chamber and attached to the puck of the carrier for fabrication processes. The combined workpiece and workpiece carrier may be handled as if it is a single wafer. The carrier protects the carried thin wafer from breaking and the combination is close in size to a standard wafer that has not been thinned. Any of a variety of different fabrication processes may be applied to the workpiece while it is in the processing chamber and attached to the carrier. During the process and optionally before the process, the dry gas is supplied under pressure to the dry gas inlet of the base plate. The pressure pushes the dry gas into the space between the base plate and the cooling plate. The gas flow drives the ambient air from between the base plate and the cooling plate.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

1. A workpiece carrier comprising:
a substrate;
an electrode formed on the substrate to carry an electric charge to grip a workpiece;
a through hole through the substrate and connected to the electrode; and
a dielectric layer over the substrate to isolate the electrode from the workpiece.

2. The workpiece carrier of claim 1, wherein the substrate comprises a silicon wafer.

3. The workpiece carrier of claim 1, wherein the electrode comprises patterned tantalum.

4. The workpiece carrier of claim 1, wherein the electrode is applied to the substrate by plasma vapor deposition.

5. The workpiece carrier of claim 1, wherein the through hole contains a conductive material to provide an electrical contact electrically coupled to the electrode.

6. The workpiece carrier of claim 1, further comprising a conductive plug over the through hole, wherein the electrode is over the plug.

7. The workpiece carrier of claim 1, further comprising a bond pad over the through hole on a side of the substrate opposite the electrode, the bond pad providing an electrical connection to the electrode from the opposite side.

8. The workpiece carrier of claim 1, wherein the electrode is on a front side of the substrate, the workpiece carrier further comprising an additional dielectric layer on the back side of the substrate.

9. The workpiece carrier of claim 8, wherein the back side dielectric is in contact with the substrate with no intervening metal layer.

10. The workpiece carrier of claim 1, further comprising a plurality of through holes extending from a back side of the substrate through the dielectric layer to provide access to a back side of the workpiece.

11. The workpiece carrier of claim 1, wherein the substrate is comprised of at least one of glass, polysilicon, and ceramic.

12. A method comprising:
forming a through hole in a substrate, the through hole extending between a first side of the substrate and a second side of the substrate as an electrical contact accessible from the second side of the substrate;
applying a conductive layer over the first side of the substrate, the conductive layer being in contact with the through hole as an electrode of an electrostatic carrier; and
applying a dielectric over the substrate and the applied layer as a surface upon which to electrostatically carry a workpiece held in place by the electrode.

13. The method of claim 12, wherein applying the conductive layer comprises applying a metal over the substrate with plasma vapor deposition.

14. The method of claim 12, wherein applying the conductive layer comprises applying a mask over the substrate and depositing a patterned electrode over the substrate as defined by the mask.

15. The method of claim 12, wherein applying the dielectric layer comprises applying an oxide by chemical vapor deposition.

16. The method of claim 12, further comprising placing a conductive plug over the through hole on the first side of the substrate before applying the conductive layer to provide the electrical contact, wherein the conductive layer is applied over the plug.

17. The method of claim 12, further comprising plating the through hole with a conductive lining that is coupled to the applied conductive layer.

18. A plasma processing system comprising:
a plasma chamber;
a plasma source to generate a plasma containing gas ions in the plasma chamber; and
a workpiece holder in the chamber having a puck to carry the workpiece for fabrication processes, a top plate thermally coupled to the puck, and a cooling plate fastened to and thermally coupled to the top plate, the cooling plate having a cooling channel to carry a heat transfer fluid to transfer heat from the cooling plate,
the workpiece being a thinned silicon wafer that is carried by workpiece carrier so that the carrier is carried by the puck, the workpiece carrier including a substrate, an electrode formed on the substrate to carry an electric charge to grip the thinned silicon wafer, a through hole through the substrate and connected to the electrode, a dielectric layer over the substrate to isolate the electrode from the thinned silicon wafer.

19. The system of claim 18, further comprising a second through hole in the substrate extending between the dielectric layer and the second side of the substrate as an access port to the thinned silicon wafer.

20. The system of claim 19, further comprising forming a vacuum fitting on the second through hole.
